(19) United States
(12) Patent Application Publication
(10) Pub. No.: US 2013/0043892 A1
(43) Pub. Date: Feb. 21, 2013

(54) RESISTANCE MEASUREMENT CIRCUIT

(71) Applicants: YI-XIN TU, Shenzhen City (CN); JIN-LIANG XIONG, Shenzhen City (CN); HAI-QING ZHOU, Shenzhen City (CN)

(72) Inventors: YI-XIN TU, Shenzhen City (CN); JIN-LIANG XIONG, Shenzhen City (CN); HAI-QING ZHOU, Shenzhen City (CN)

(73) Assignees: HON HAI PRECISION INDUSTRY CO., LTD., Tu-Cheng (CN); HONG FU JIN PRECISION INDUSTRY (ShenZhen) CO., LTD., Shenzhen City (CN)

(21) Appl. No.: 13/249,377

(22) Filed: Sep. 30, 2011

(30) Foreign Application Priority Data
Aug. 17, 2011 (CN) 201110235979.7

(51) Int. Cl. G01R 27/02

(52) U.S. Cl. 324/691

(57) ABSTRACT

A resistance measuring circuit for measuring a resistor includes an amplifier, a transistor, a variable resistor, a first resistor, and a second resistor. The transistor includes a base connected to the output of the amplifier, a collector connected to a direct current (DC) power supply, and an emitter. The first resistor includes a first terminal connected to the DC power source, and a second terminal grounded through the variable resistor and connected to the non-inverting terminal of the amplifier. The second resistor includes a first terminal connected to the inverting terminal of the amplifier and connected to the emitter of the transistor through the resistor to be measured, and a second terminal grounded.

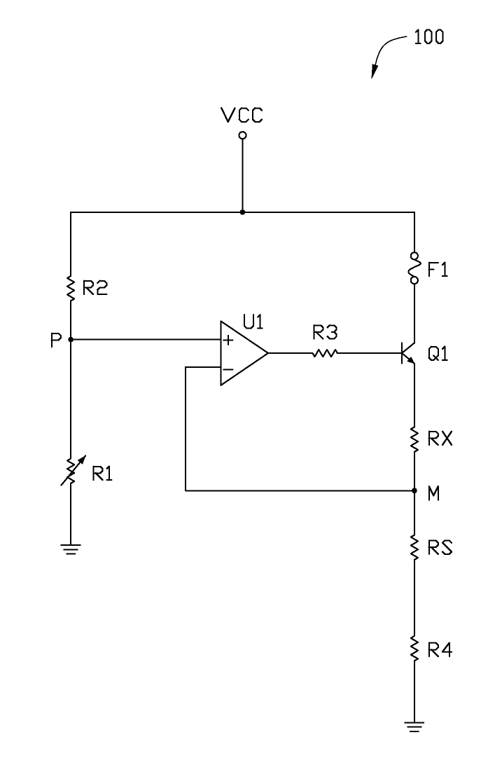

### BACKGROUND

1. Technical Field

The present disclosure relates to a resistance measurement circuit.

2. Description of Related Art

Multimeters are known to have low resolution, and cannot accurately measure small resistance values, such as in the milliohm range. An expensive bridge or specialized instrument must be purchased to take such measurements, which is costly.

### BRIEF DESCRIPTION OF THE DRAWING

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

The FIGURE is a circuit diagram of an exemplary embodiment of a resistance measurement circuit.

### DETAILED DESCRIPTION

The disclosure is illustrated by way of example and not by way of limitation in the FIGURE of the accompanying drawings in which like references indicate similar elements. It should be noted that references to “an” or “one” embodiment in this disclosure are not necessarily to the same embodiment, and such references mean at least one.

Referring to the FIGURE, an exemplary embodiment of a resistance measurement circuit 100 for measuring resistance of a resistor RX includes an amplifier U1 having a non-inverting terminal, an inverting terminal, and an output, a transistor Q1 having a base, an emitter, and a collector, a variable resistor R1, a resistor RS whose impedance is known, a fuse F1, and resistors R2-R4.

A first terminal of the resistor R2 is connected to a direct current (DC) power source, and a second terminal of the resistor R2 is grounded through the variable resistor R1. The non-inverting terminal of the amplifier U1 is connected to a node P between the resistor R2 and the variable resistor R1. The output of the amplifier U1 is connected to the base of the transistor Q1 through the resistor R3. The collector of the transistor Q1 is connected to the DC power source through the fuse F1. The emitter of the transistor Q1 is grounded through the resistor RX to be measured, the resistor RS, and the resistor R4 in that order. The inverting terminal of the amplifier U1 is connected to a node M between the resistor RX to be measured and the resistor RS.

The resistor RS has a known impedance, such as 1 ohm. A multimeter is used to measure a voltage Uₛ of the resistor RS, therefore, the current Iₛ flowing through the resistor RS can be calculated as Iₛ=Us/Rs. The current Iₛ is equal to the current flowing through the resistor RX to be measured. The voltage Ux across the resistor RX to be measured is measured by the multimeter, therefore, the impedance of the resistor RX can be calculated as RX=Uₓ/Iₛ.

The amplifier U1 and the transistor Q1 are used for amplifying the current Iₛ. Adjusting the impedance of the variable resistor R1 can adjust the voltage at the non-inverting terminal of the amplifier U1, thereby adjusting the current Iₛ flowing through the emitter of the transistor Q1 and the resistor RX. When the current Iₛ is adjusted to be a relatively great value, the voltage Us of the resistor RS and the voltage Uₓ of the resistor RX will also have a relatively great value in a range that can be accurately measured by the multimeter.

The fuse F1 is connected between the DC power and the collector of the transistor Q1 to protect the transistor Q1.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A resistance measuring circuit for measuring resistance of a resistor, the resistance measuring circuit comprising:
an amplifier comprising a non-inverting terminal, an inverting terminal, and an output;
a transistor comprising a base connected to the output of the amplifier, a collector connected to a direct current (DC) power supply, and an emitter;
a variable resistor;
a first resistor comprising a first terminal connected to the DC power, and a second terminal grounded through the variable resistor and connected to the non-inverting terminal of the amplifier; and
a second resistor comprising a first terminal connected to the inverting terminal of the amplifier and connected to the emitter of the transistor through the resistor to be measured, and a second terminal grounded, wherein the impedance of the second resistor is known.

2. The resistance measuring circuit of claim 1, further comprising a third resistor, wherein the second terminal of the second resistor is grounded through the third resistor.

3. The resistance measuring circuit of claim 1, further comprising a fuse connected between the collector of the transistor and the DC power.

4. The resistance measuring circuit of claim 1, further comprising a third resistor connected between the output of the amplifier and the base of the transistor.
